(19) United States
(12) Patent Application Publication
(10) Pub. No.: US 2009/0167387 A1
(43) Pub. Date: Jul. 2, 2009

(54) DELAY-LOCKED LOOP FOR TIMING CONTROL AND DELAY METHOD THEREOF

(75) Inventor: Jeong Min KIM, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/277,960

(22) Filed: Nov. 25, 2008

(30) Foreign Application Priority Data
Dec. 26, 2007 (KR) 10-2007-0137645

(51) Int. Cl. H03L 7/06

(52) U.S. Cl. 327/157; 327/158

(57) ABSTRACT

A delay-locked loop for timing control, includes a voltage-controlled delay line that delays a reference clock to generate a multi-phase clock comprising a plurality of delayed phase clocks; and an up/down controller that receives one of the delayed phase clocks as a feedback clock and generates a frequency up/down control signal based on whether a rising edge of the feedback clock coincides with a falling edge of the reference clock. The delay-locked loop further includes a charge pump that charges or discharges a loop filter connected to the voltage-controlled delay line according to a frequency up/down control signal from the up/down controller; and a harmonic lock detector that compares phases of multiple ones of the delayed phase clocks with a phase of the reference clock, and operates such that the multi-phase clock is locked within a first cycle of the reference clock.

### CROSS-REFERENCE TO RELATED APPLICATION

This application claims priority to Korean Application No. 10-2007-0137645, filed on Dec. 26, 2007, which is incorporated herein by reference in its entirety.

### BACKGROUND

1. Field of the Invention

Embodiments of the present invention relate to a delay-locked loop and delay method thereof that provide, among other advantages, a stable operation at a low frequency.

2. Description of Related Art

In recent years, with an increase in a bandwidth required by systems, a technology that reduces a skew by using a phase-locked loop (PLL) or a delay-locked loop (DLL) has become increasingly important. In particular, the DLL is widely used as a zero delay buffer since it has superior stability and jitter characteristics compared to the PLL.

Such a delay-locked loop delays an input reference clock by an integer cycle and generates a synchronized local clock.

FIG. 1 is a block diagram showing a configuration of a known delay-locked loop. The known delay-locked loop includes an up/down controller 100, a charge pump 102, a voltage-controlled delay line (VCDL) 104, and a harmonic lock detector 106.

The up/down controller 100 applies an up control signal UP or a down control signal DOWN to the charge pump 102 so as to move up or down the phase of the multi-phase clock output from the voltage-controlled delay line 104. Then, the charge pump 102 stores an electric charge in a capacitor 103 of a low pass filter.

As shown in FIG. 2, the voltage-controlled delay line 104 divides the phase of a reference clock by an integer, ‘n’, with edges from each delay cells of the voltage controlled delay line, and generates a multi-phase clock comprising ‘n’ number of delayed phase clocks having predetermined delay therebetween, rising edges are being made with 45°, 90°, 135° and 180°.

In the known delay-locked loop, there is a problem in detecting harmonic lock and ensuring a stable operation at a low frequency. In addition, as a voltage in the voltage-controlled delay line becomes lower, it is difficult to maintain the duty ratio of the output multi-phase clock at 50%. These problems adversely affect other blocks which utilize the phase, and cause an abnormal operation at a low frequency.

### SUMMARY OF SOME EXAMPLE EMBODIMENTS

In general, example embodiments of the invention relate to a delay-locked loop and delay method thereof that provide advantages such as a stable operation at a low frequency. For example, by accurately adjusting the duty ratio of a multi-phase clock to 50:50 and accurately detecting and suppressing harmonic lock of the multi-phase clock, stable operation at a low frequency is provided.

According to one embodiment, a delay-locked loop for timing control includes a voltage-controlled delay line that delays a reference clock to generate a multi-phase clock comprising a plurality of delayed phase clocks; and an up/down controller that receives one of the delayed phase clocks as a feedback clock and generates a frequency up/down control signal based on whether the feedback clock coincides with a falling edge of the reference clock. The delay delay-locked loop for timing control further includes a charge pump that charges or discharges a loop filter connected to the voltage-controlled delay line according to a frequency up/down control signal from the up/down controller; and a harmonic lock detector that receives multiple ones of the delayed phase clocks from the voltage-controlled delay line, compares phases of the multiple ones of the delayed phase clocks with a phase of the reference clock, and operates such that the multi-phase clock is locked within a first cycle of the reference clock.

According to another embodiment, a method for delaying a reference clock with a delay-locked loop includes delaying the reference clock so as to generate a delayed clock, adjusting a delay imposed by the delay line based on a comparison of the reference clock with the delayed clock, and preventing a harmonic lock in the delayed clock such that the delayed clock is locked within a first cycle of the reference clock.

Accordingly, in the exemplary delay-locked loop and delay method thereof, the duty ratio of the multi-phase clock may be accurately adjusted to 50:50 by using a duty corrector, and harmonic lock of the multi-phase clock may be accurately detected and suppressed. Therefore, a stable operation at a low frequency can be performed, and as a result operation stability of a circuit can be significantly improved.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

Aspects of example embodiments of the invention will become apparent from the following description of example embodiments given in conjunction with the accompanying drawings, in which:

FIG. 1 is a block diagram showing the configuration of a known delay-locked loop;

FIG. 2 is a diagram of a delayed multi-phase clock which is output from the known delay-locked loop;

FIG. 3 is a block diagram showing the configuration of a delay-locked loop according to an embodiment of the present invention;

FIG. 4 is a diagram showing a logic circuit of an up/down controller according to an embodiment of the present invention;

FIG. 5 is a diagram showing a logic circuit of a duty corrector according to an embodiment of the present invention; and

FIG. 6 is a diagram showing a logic circuit of a harmonic lock detector according to an embodiment of the present invention.

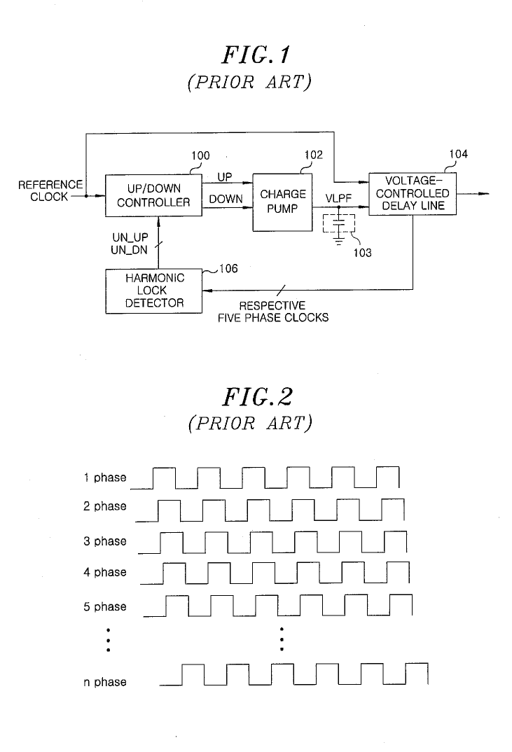

### DETAILED DESCRIPTION OF SOME EXAMPLE EMBODIMENTS

In the following detailed description of the embodiments, reference is made to the accompanying drawings that show, by way of illustration, specific embodiments of the invention. In the drawings, like numerals describe substantially similar components throughout the several views. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

In general, embodiments of the present invention relate to a delay-locked loop. In one embodiment the duty ratio of a multi-phase clock is accurately adjusted to 50:50 by using a duty corrector, and harmonic lock of the multi-phase clock is accurately detected and suppressed, thereby providing stable operation at a low frequency.

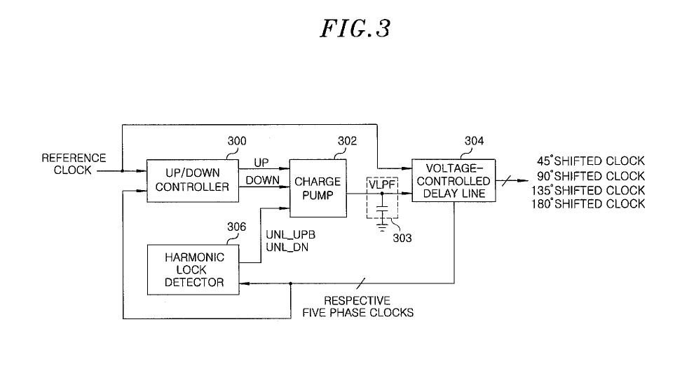

FIG. 3 is a block diagram showing an example configuration of a delay-locked loop according to an embodiment of the present invention. The delay-locked loop may include an up/down controller 300, a charge pump 302, a voltage low pass filter (VLPF) 303, a voltage-controlled delay line 304, and a harmonic lock detector 306.

As described above, in a conventional delay-locked loop, there is a problem in detecting harmonic lock and ensuring a stable operation at a low frequency. In addition, maintaining the duty ratio of an output multi-phase clock in a voltage-controlled delay line at 50:50 is desirable in some applications.

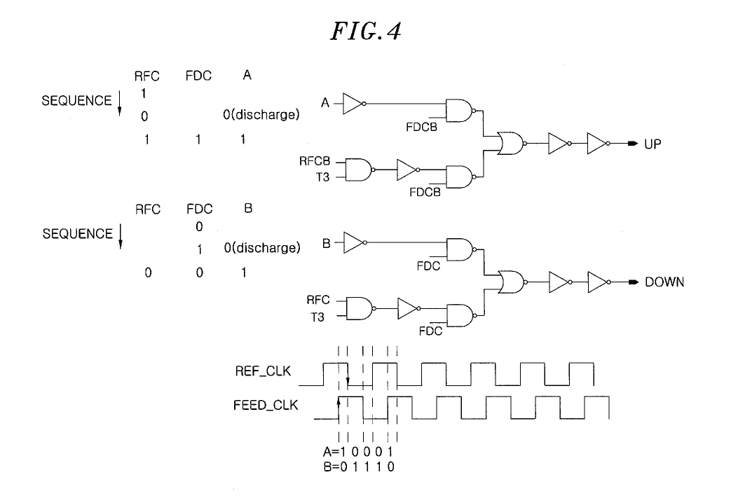

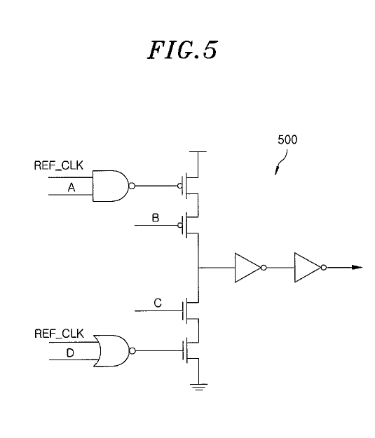

FIG. 4 shows an up/down control signal output logic in the up/down controller 300 of the delay-locked loop shown in FIG. 3.

As shown in FIG. 4, an up control signal UP or a down control signal DOWN are generated by the up/down controller 300 for locking the multi-phase clock from the voltage-controlled delay line 304 to the reference clock. For example, the up/down controller 300 may lock the multi-phase clock to the reference clock by matching the falling edge of the reference clock REF_CLK (i.e., RFC) and the rising edge of a multi-phase feedback clock FEED_CLK (i.e., FDC) from the voltage-controlled delay line 304.

This matching function of the up/down controller 300 will be described below in detail. In one embodiment, the voltage-controlled delay line 304 may generate a multi-phase clock having, for example, 18 phase clocks in total. Then, the up/down controller 300 may compare the rising edge of a ninth phase clock among the generated multi-phase clock (i.e., a delayed phase clock delayed by nine delay increments) with a falling edge of the reference clock. When the rising edge of the feedback clock is faster than the falling edge of the reference clock, the down control signal DOWN may be generated to delay the feedback clock such that the rising edge of the feedback clock matches or coincides with the falling edge of the reference clock. When the rising edge of the feedback clock is slower than the falling edge of the reference clock, the up control signal UP may be generated to advance the rising edge of the feedback clock such that the rising edge of the feedback clock matches or coincides with the falling edge of the reference clock.

If various frequency bandwidths are used, a clock generated by the voltage-controlled delay line 304 at a low frequency has cycles that exceed in time one cycle of the reference clock. Accordingly, data to be compared in the logic becomes incorrect, and the up control signal and the down control signal are undesirably generated. In order to solve this problem, a window signal T3 with the phase of a third clock in the multi-phase clock from the voltage-controlled delay line 304 (i.e., a clock with phase delayed by 3/n with respect to the reference clock) is generated, such that the up or down control signal is generated only when the window signal T3 is in the high level.

FIG. 5 shows a logic circuit of a duty corrector 500 in a voltage-controlled delay line according to one embodiment of the present invention. The duty corrector 500 may be provided to adjust the duty ratio of a multi-phase clock output from the voltage-controlled delay line 304 such that the duty ratio is maintained at 50:50.

Referring to FIG. 5, the duty corrector 500 may be provided at the output stage of the voltage-controlled delay line 304. The duty corrector 500 may use the rising edge of the multi-phase clock from the voltage-controlled delay line 304 to adjust the duty ratio since the falling edge of the multi-phase clock from the voltage-controlled delay line 304 is not accurately consistent with the reference clock REF_CLK, as described above.

The duty corrector 500 may include logic configured to restrict an operation region such that an operation at a low frequency is implemented and such that inversion does not occur at low clock speed. For example, the duty corrector 500 may be configured to compare the phase of the reference clock REF_CLK and the phases of four phase clocks from the voltage-controlled delay line 304. The four phase clocks may be divided into a logic high region and a logic low region. For example, the logic high region may include two of the four phase clocks having preceding edges, and the logic low region may include the other two of the four phase clocks having succeeding edges.

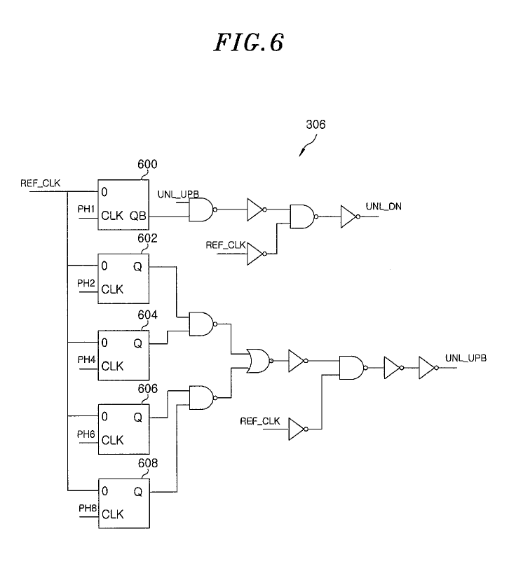

FIG. 6 shows a logic circuit of the harmonic lock detector 306 shown in FIG. 3 according to an embodiment of the present invention.

In this particular example, the harmonic lock detector 306 is implemented with five D latches 600, 602, 604, 606, and 608, which receive the reference clock and a plurality of, e.g., four, multi-phase clocks from the voltage-controlled delay line 304. The phases of the second, fourth, sixth, and eighth phase clocks PH2, PH4, PH6, and PH8 are detected by the second to fifth D latches 602, 604, 606, and 608. Then, when the values Q of the D latches are all logic high by virtue of the reference clock REF_CLK, UNL_UPB, i.e., an up-signal for preventing a harmonic lock when a locking is not able to be performed, is maintained to be logic high, and the up control signal is applied to the charge pump 302.

Accordingly, the up control signal is continuously applied to the charge pump 302 regardless of the signal from the up/down controller 300. Therefore, a locking operation of the multi-phase clock output from the voltage-controlled delay line 304 is performed within the first cycle of the reference clock REF_CLK. As a result, harmonic lock is suppressed.

Meanwhile, when the multi-phase clock from the voltage-controlled delay line 304 has a more advanced phase than the reference clock, the first D latch 600 detects the multi-phase clock, and UNL_DN, i.e., a down-signal for preventing the harmonic lock when the locking is not able to be performed, becomes logic high. Therefore, the down control signal is applied to the charge pump 302.

As described above, according to an embodiment of the present invention, in the delay-locked loop, the duty ratio of the multi-phase clock is accurately adjusted to 50:50 by using the duty corrector, and harmonic lock of the multi-phase clock is accurately detected and suppressed. Therefore, a stable operation at a low frequency can be provided, and as a result operation stability of the circuit can be significantly improved.

While the invention has been shown and described with respect to the embodiment, it will be understood by those skilled in the art that various changes and modifications may be made without departing from the scope of the invention as defined in the following claims.

What is claimed is:

1. A delay-locked loop, comprising:
a voltage-controlled delay line that delays a reference clock to generate a multi-phase clock comprising a plurality of delayed phase clocks;
an up/down controller that receives one of the delayed phase clocks as a feedback clock and generates a frequency up/down control signal based on whether a rising edge of the feedback clock coincides with a falling edge of the reference clock;
a charge pump that charges or discharges a loop filter connected to the voltage-controlled delay line according to the frequency up/down control signal from the up/down controller; and
a harmonic lock detector that receives multiple ones of the delayed phase clocks from the voltage-controlled delay line, compares phases of the multiple ones of the delayed phase clocks with a phase of the reference clock, and operates such that the multi-phase clock is locked within a first cycle of the reference clock.

2. The delay-locked loop of claim 1, wherein the plurality of delayed phase clocks includes 18 incrementally delayed phase clocks and wherein the up/down controller receives a ninth one of the delayed phase clocks, delayed by nine delay increments, as the feedback clock.

3. The delay-locked loop of claim 1, wherein, when the rising edge of the feedback clock is faster than the falling edge of the reference clock, the up/down controller generates a down signal to delay the feedback clock such that the rising edge of the feedback clock coincides with the falling edge of the reference clock.

4. The delay-locked loop of claim 3, wherein, when the rising edge of the feedback clock is slower than the falling edge of the reference clock, the up/down controller generates an up signal to advance the feedback clock such that the rising edge of the feedback clock coincides with the falling edge of the reference clock.

5. The delay-locked loop of claim 1, wherein the harmonic lock detector includes D latches that receive the reference clock and the multiple ones of the delayed phase clocks, and if it is determined that the output of each of the D latches is logic low and harmonic lock is generated, an up control signal is applied to the charge pump to advance the feedback clock within one cycle of the reference clock.

6. The delay-locked loop of claim 1, wherein the voltage-controlled delay line includes a duty corrector that compares the phases of four of the delayed phase clocks generated by the voltage-controlled delay line and a phase of the reference clock and operates such that the duty ratio of the multi-phase clock becomes 50:50.

7. The delay-locked loop of claim 6, wherein the duty correction is performed by using a rising edge of the multi-phase clock.

8. The delay-locked loop of claim 1, wherein the down control signal is applied to the charge pump when the multi-phase clock from the voltage-controlled delay line has a more advanced phase than the reference clock.

9. A delay-locked loop comprising:
a delay line configured to delay a reference clock so as to generate a delayed clock;
a controller configured to adjust a delay imposed by the delay line based on a comparison of the reference clock with the delayed clock;
a harmonic lock detector configured to prevent a harmonic lock such that the delayed clock is locked within a first cycle of the reference clock.

10. The delay-locked loop of claim 9, wherein the delay line is voltage controlled.

11. The delay-locked loop of claim 9, further comprising a capacitor positioned at an input of the delay line.

12. The delay-locked loop of claim 11, wherein the capacitor is charged or discharged according to a control signal generated by the controller.

13. The delay-locked loop of claim 12, wherein the capacitor is charged via a charge pump.

14. A method for delaying a reference clock with a delay-locked loop, the method comprising:
delaying the reference clock so as to generate a delayed clock;
adjusting a delay imposed by the delay line based on a comparison of the reference clock with the delayed clock;
preventing a harmonic lock in the delayed clock such that the delayed clock is locked within a first cycle of the reference clock.
